(19) United States
(12) Patent Application Publication
(10) Pub. No.: US 2026/0194479 A1
(43) Pub. Date: Jul. 9, 2026

(54) Nuclear Magnetic Resonance Measurements on Electrical Components Such as in Particular Batteries and Capacitors

(71) Applicant: Forschungszentrum Jülich GmbH, Jülich (DE)

(72) Inventors: Peter Philipp Maria Schleker, Eschweiler (DE); Josef Karl Granwehr, Jülich (DE); Peter Jakes, Jülich (DE); Christian Hellenbrandt, Linnich (DE); Rüdiger-A Eichel, Jülich (DE)

(21) Appl. No.: 19/131,670

(22) PCT Filed: Nov. 24, 2023
(86) PCT No.: PCT/EP2023/082950

§ 371 Date: May 21, 2025

(30) Foreign Application Priority Data
Nov. 28, 2022 (DE) 10 2022 131 403.0

(51) Int. Cl. G01N 24/08

(52) U.S. Cl. CPC G01N 24/08

(57) ABSTRACT

A method allows for nuclear magnetic resonance measurements to be carried out on electrical components such as batteries or capacitors. In the process, the component is directly integrated in a resonant circuit of a nuclear magnetic resonance probe head in that the poles are electrically connected to the other elements of the resonant circuit, and the probe head is then introduced in a temporally and spatially constant magnetic field. Pulsed nuclear magnetic resonance measurements are carried out, in which a spin resonance signal is generated by at least one high-frequency pule and is recorded. The spectrum formed from this spin resonance signal is dependent on the state of the component, in particular on the state of charge of a battery or on the general state of the battery or the capacitor.

The subject matter of the present invention is a method for carrying out NMR (nuclear magnetic resonance) measurements on electrical components such as in particular batteries and capacitors.

Batteries, and also capacitors, have electrical connections which are not electrically connected to one another in the interior of the battery or the capacitor by a continuous electrical conductor. Rather, in the case of a capacitor, a dielectric material, for example, is formed between two electrodes, wherein the electrodes are electrically connectable to other elements via poles. Alternatively, an electrolyte can also be formed between the electrodes of the capacitor, wherein in this case a dielectric material is formed at least at one electrode. In the case of a battery, the poles of the battery are also connected to electrodes, which are not connected to one another in the interior of the battery via a continuous electrical conductor, but rather between which an electrolyte is formed that permits the movement of ions toward the electrodes of the battery and at the same time prevents the movement of electrons between the electrodes.

Batteries and capacitors share the feature that they comprise metallic components. Metallic components typically result in problems when carrying out NMR measurements, since the metallic components result in artifacts in the acquired measurement signal. At the same time, the skin effect has the result that a normal NMR measurement is only possible in a very restricted manner on samples having an externally closed metallic shell, since the high-frequency pulses necessary for carrying out the NMR measurement only result in effects on the surface of the metallic component and a penetration of the high-frequency pulse into the depth of the sample is effectively not possible.

Proceeding therefrom, the invention is based on the object of enabling an NMR measurement on electrical components such as in particular batteries and capacitors. This object is achieved by the features of the independent claim. The dependent claims are directed to advantageous refinements.

As a precaution, it is to be noted that the counting words used here (“first”, “second”, . . . ) are predominantly (only) used to distinguish multiple equivalent objects, dimensions or processes, and they thus do not necessarily specify a dependence and/or sequence of these objects, dimensions or processes in relation to one another. If a dependence and/or sequence should be necessary, it is explicitly indicated here or it results in an obvious manner for a person skilled in the art upon studying the specifically described embodiment.

The method according to the invention for examining an electrical component having a first pole and a second pole, wherein the component is electrically connectable via the poles, wherein the component comprises two electrodes, wherein one electrode is electrically connected to precisely one pole in each case and the component does not have a metallic connection between the electrodes, wherein a substance is formed in the component between the electrodes, wherein the component is subjected to a temporally constant magnetic field and a high-frequency field switched in pulses and the data are measured in the form of at least one spin resonance signal, is distinguished in that the component is electrically incorporated into a resonant circuit via its poles, via which the high-frequency field is excited within the component and the spin resonance signal is recorded.

The poles are understood as the connections via which the electrical component is typically electrically connected to other elements. For example, a primary battery or a secondary battery comprises a “+” pole and a “−” pole. In a capacitor, the electrical connections of the capacitor are understood as poles in the meaning of this document. No metallic connection exists between the electrodes in the interior of the component. This is the case, for example, with batteries or capacitors. Batteries and capacitors would be short-circuited if a metallic connection were present between the poles. Batteries comprise in particular primary and secondary batteries of the structural forms AA, AAA, 21700, 18650, 26650, 4680, button cells, and also pouch cells and Swagelok cells.

The temporally constant magnetic field is referred to as a BO field. It is preferably generated by an electromagnet or a superconducting magnet. Alternatively, a permanent magnet can also be used to generate the BO field. Smaller additional magnetic fields can preferably be overlaid for homogenizing the temporally and spatially constant magnetic field. Alternatively, a deliberately spatially inhomogeneous, but temporally constant, magnetic field can be generated by overlaying one or more further magnetic fields, so that only specific spatial areas are excited to resonance by the high-frequency field switched in pulses or even an imaging method can be achieved by a deliberate spatial change of the temporally constant magnetic field.

The magnetic flux density of the BO field determines the resonance frequency within the magnetic field for an atomic nucleus to be examined using the NMR measurement, for example 1-hydrogen (¹H) or 7-lithium (⁷Li), which is also referred to as the Larmor frequency. The resonant circuit preferably comprises at least two tunable capacitors, via which, on the one hand, the resonant circuit can be tuned to the resonance frequency (also referred to as “tuning”) and, on the other hand, a signal maximization of the spin resonance signal and a reduction of reflections of the high-frequency signal can be achieved (also referred to as “matching”), by which the impedance of the resonant circuit is adapted. The two capacitors can accordingly be referred to as tune and match. The natural frequency of the resonant circuit can be adapted to the respective isotope to be examined by tuning the capacitors. In particular if an electromagnet is used, the magnetic field could alternatively or additionally also be adapted. The high-frequency field is a magnetic high-frequency field, the frequency of which is determined in a typical manner depending, inter alia, on the BO field and the atomic nucleus to be examined.

The substance is preferably a gas, a liquid or a solid. The substance is preferably an electrolyte and/or a dielectric material.

The incorporation of the component into the resonant circuit refers to establishing an electrical connection between the poles of the component and the other elements of the resonant circuit by electrical contacting. The incorporation of the component in particular does not comprise capacitive coupling or the like.

Due to the incorporation of the component into the resonant circuit, the electrodes of the component and/or the current collectors are incorporated into the resonant circuit and emit the high-frequency field into the substance and therefore into the interior of the component and in turn record the spin resonance signal, which characterizes the component. The signal generation of the high-frequency field and the recording of the spin resonance signal take place via the typical electronics of an NMR spectrometer, which comprise, for example, corresponding frequency synthesizers and amplifiers. The electrodes act more or less as an inductor here, in particular as a coil, in the resonant circuit. Thus instead of introducing the component into the typical coil of an NMR probe head, the electrodes of the component are used as a coil in the NMR measurement. Surprisingly, reproducible NMR measurements can thus be carried out on components such as batteries or capacitors. The NMR spectra obtained are reproducible and depend on the structure and status of the component.

In particular, it is possible by way of the method described here to measure commercially available batteries and capacitors using NMR, even if they have a metallic housing. The obtained NMR spectra of batteries are battery-individual, i.e. the batteries of different producers have different spectra, and status-individual. The obtained spectra are thus also reproducibly individual for different states of charge and numbers of charge cycles. This also applies similarly to the measurement of capacitors. The method indicated here can thus be used to characterize electrical components such as batteries or capacitors.

The resonant circuit preferably comprises at least two tunable capacitors, via which the frequency and the impedance of the resonant circuit are adaptable. It is therefore possible to adapt the obtained spin resonance signal to the local BO field at the location of the component. The two tunable capacitors enable “tuning” and “matching” as described above. Alternatively, it is also possible to provide one or more tunable coils. Due to the tunability by capacitors and/or coils or other elements, the resonant circuit can be adapted to different resonance frequencies with given temporally constant magnetic field, and therefore to different nuclei.

The component preferably comprises a battery or a winding for battery. A battery preferably comprises two conductive electrodes. The electrodes are preferably formed from a ceramic material which is provided with a conductive material. The conductive material is preferably a material comprising carbon, in particular conductive carbon black and/or carbon. An electrode material, which is used for ion intercalation and to which an electrolyte is connected, is applied to the electrodes. The electrodes are separated by a separator, which represents an electrical insulation for preventing an electrical short circuit and a mechanical partition between the electrodes. The substance preferably comprises an electrolyte. A medium which is electrically conductive due to ions contained therein is referred to as an electrolyte. The electrolyte is preferably liquid, a solid, a melt, a gel or a polymer material or comprises a mixture of at least two of the aforementioned materials. In a battery, the electrolyte is used to bring about the charge equalization between the electrodes (cathode and anode).

In particular, the described method can be used to examine a battery of type 18650. The designation “type 18650” is generally used for a cylindrical battery having a diameter of 18 mm and a length of 65 mm. It has been shown that the concept of the method described herein can be applied in particular to this industrially important battery type. For this purpose, the battery of type 18650 is incorporated into a resonant circuit as a resonator as described and examined by means of NMR.

The described method can in particular be used to detect and to characterize specific isotopes or elements within a closed battery by means of NMR. It is possible by way of the described method to compare batteries from different producers to one another. This is expedient in particular in order to compare batteries having defined specifications to one another. This is the case, for example, for batteries of type 18650. It is also possible in particular by way of the described method to determine the chemistry of a battery cell.

The component to be examined does not have to comprise a complete battery. It is therefore preferred for the component to comprise, instead of a battery as such, only a winding for a battery. This applies in particular to batteries of type 18650, but in addition also for batteries in general. If a battery is used as the electrical component, the NMR measurement according to the method described here can thus be used to collect data about the battery and/or about the substance. In particular in the case of secondary batteries, i.e. rechargeable batteries, structural and chemical changes occur within the battery due to the charging and discharging cycles, which are noticeable in the measured NMR spectra due to changes. This also applies accordingly to primary batteries. The method presented here thus permits a characterization of a battery depending on the state of charge, on the structural status, age, etc. It is possible by way of the performance of the NMR measurement as described here on a battery to generate a spin resonance signal which originates not only from the substance between the electrodes, but is also influenced by the electrodes themselves. It is thus possible by way of the method described here to measure changes of the electrode or of the electrode material, in particular structural and chemical changes such as a corrosion of one or both electrodes.

The component preferably comprises a capacitor. The substance preferably comprises a dielectric material. A dielectric material is understood as a substance which is weakly electrically conductive or is nonconductive, and in which the existing charge carriers are freely movable or can be polarized. The dielectric material is preferably a liquid or a solid. Alternatively, gaseous dielectric materials such as air are also possible. The dielectric material preferably has a relative permittivity of at least 1. Furthermore, the substance of the capacitor preferably comprises an electrolyte which is formed between the electrodes.

If a capacitor is used as the electrical component, the NMR measurement according to the method described here can be used to collect data about the capacitor and in particular about the dielectric material of the capacitor and/or the electrodes of the capacitor. In particular, data can be collected using the method described here which permit a statement on the structural and chemical status of the capacitor. In particular with expensive capacitors or else so-called super capacitors, it is advantageous to be able to characterize them in order to be able to separate out flawed capacitors in order for example to be able to track aging processes in the capacitor. Using the method described here, it is preferably possible to carry out NMR measurements on ceramic capacitors, electrolyte capacitors, double-layer capacitors, film capacitors and plate capacitors. The measurement on so-called super capacitors, which are designed as electrochemical capacitors, is particularly preferred.

Preferably, the resonance frequency and/or the intensity of one of the following atomic nuclei is determined on the basis of the magnetic flux density of the temporally constant magnetic field: 1-hydrogen (¹H); 6-lithium (⁶Li); 7-lithium (⁷Li); 13-carbon (¹³C); 14-nitrogen (¹⁴N); 19-fluorine (¹⁹F); 23-sodium (²³Na); 27-aluminum (²⁷AI); 29-silicon (²⁹Si); 31-phosphorus (³¹P); 39-potassium (³⁹K) ; 59-cobalt (⁵⁹Co), 111-cadmium (¹¹¹Cd), 113-cadmium (¹¹³Cd) or 207-lead (²⁰⁷Pb), and this resonance frequency is used as the frequency of the high-frequency field. Fe, Mn, Zn, Ti, V, Cd and Cu can also be used. The resonance frequency takes into consideration, in addition to the actual Larmor frequency, in particular also the corresponding chemical shift. The method described here permits NMR measurements to be carried out on electrical components such as capacitors or batteries, in which a spin resonance signal can be generated by the selection of one of the above-mentioned atomic nuclei depending on the structure and the composition of the substance, which signal is used to characterize the status of the battery or of the capacitor. By measuring the mentioned isotopes, statements can be made on the status of the examined component. This applies in particular in the case of a battery as the examined component. In particular, it is possible to examine a sodium ion battery by the detection of 23-sodium (²³Na) and to detect the various states of the element sodium, in particular metallic and solvated Na⁺. This applies accordingly to 6-lithium (⁶Li) and 7-lithium (⁷Li).

Alternatively, it is preferred to perform an isotope enrichment on the component and then to use the resonance frequency of at least one of the following atomic nuclei: 2-hydrogen (²H), 15-nitrogen (¹⁵N); 17-oxygen (¹⁷O) or 33-sulfur (³³S). Preferably, the resonance frequency of one of the following atomic nuclei is determined and this resonance frequency is used as the frequency of the high-frequency field: 25-magnesium (²⁵Mg), 35-chlorine and 37-chlorine (³⁵Cl and ³⁷Cl), 47-titanium and 49-titanium (⁴⁷Ti and ⁴⁹Ti), 51-vanadium (⁵¹V), 57-iron (⁵⁷Fe), 55-manganese (⁵⁵Mn), 59-cobalt (⁵⁹Co), 61-nickel (⁶¹Ni), 63-copper and 65-copper (⁶³Cu and ⁶⁵Cu), 73-germanium (⁷³Ge), 89-yttrium (⁸⁹Y), 91-zirconium (⁹¹Zr), 107-silver and 109-silver (¹⁰⁷Ag and ¹⁰⁹Ag), 127-iodine (¹²⁷I) and 139-lanthanum (¹³⁹La).

The component preferably has a cylindrical structure having a cylinder axis, and the cylinder axis is aligned in the direction of the magnetic flux of the temporally and spatially homogeneous magnetic field. In this way, a signal maximization of the spin resonance signal is achieved for cylindrical components. This is preferred in particular for elongated cylinders, such as AA or AAA batteries, in which an end surface of the cylinder is smaller than the lateral surface of the cylinder.

The component preferably has a flat structure having two largest surfaces opposite to one another, and the component is aligned so that the largest surface is aligned in the direction of the magnetic flux of the temporally and spatially homogeneous magnetic field. A flat structure is preferably understood in this context as cuboid or flat cylindrical components. Cuboid components such as batteries are regularly used, for example in mobile telephones and the like. The structure as a cuboid causes at least two surfaces of the cuboid to be largest surfaces, in particular if at least two of the surfaces are rectangular and not square surfaces. “Largest surfaces” means in particular that the area of these surfaces is greater than the area of the other surfaces. Due to the structure as a cuboid, two largest surfaces are opposite to one another. A flat cylindrical geometry is distinguished in that the end surface of the cylinder is larger than the lateral surface of the cylinder. Button cells represent one example of flat cylindrical components. Due to the structure in particular of a battery, the alignment of a largest surface in the direction of the magnetic flux of the temporally and spatially homogeneous magnetic field can cause a signal maximization of the spin resonance signal.

The temporally constant magnetic field is preferably spatially constant, in the scope of a predetermined measurement accuracy or line width. This enables spectroscopic measurements of the entire component.

The temporally constant magnetic field preferably has a gradient at least in one spatial direction. This enables, on the one hand, a formation of the temporally constant magnetic field precisely such that only a predeterminable section of the component is resonant and therefore contributes to the spin resonance signal. On the other hand, it is thus possible to generate a one-dimensional, two-dimensional, or even three-dimensional location resolution and thus to apply imaging methods (MRI, magnetic resonance imaging).

The method described here is preferably used to carry out high field NMR experiments (in particular using a temporally constant magnetic field of at least 10 mT [millitesla]) on commercial batteries, which are preferably located in a metal housing. The use of the method described here for the nondestructive quality control of batteries and capacitors is particularly preferred, for example by comparison to a reference spectrum defining a standard. The method described here is preferably used to determine the state of charge of a battery, for example by comparison to reference spectra. The method described here is preferably used to determine degradation and aging processes of batteries and capacitors, for example due to change of resonances (frequency, phase, amplitude, width or line shape), disappearance of specific resonances, or additionally appearing resonances. The method described here is preferably used to characterize a degradation of the electrolyte and of the electrode materials of a battery and to represent a corresponding quality control. The method according to the invention is preferably also used to monitor the magnetization of a component. The change of the magnetization of a component, for example of a battery, is shown by a spectrum shifted toward other frequencies. The invention and the technical environment are explained in more detail hereinafter on the basis of the figures. It is to be noted that the invention is not intended to be restricted by the exemplary embodiment shown. In particular, unless explicitly indicated otherwise, it is also possible to extract partial aspects of the substantive matter explained in the figures and to combine them with other component parts and findings from the present description and/or figures. In particular, it is to be noted that the figures and in particular the size ratios shown are only schematic. Identical reference signs identify identical objects, and so explanations from other figures can possibly be used as supplements. In the figures:

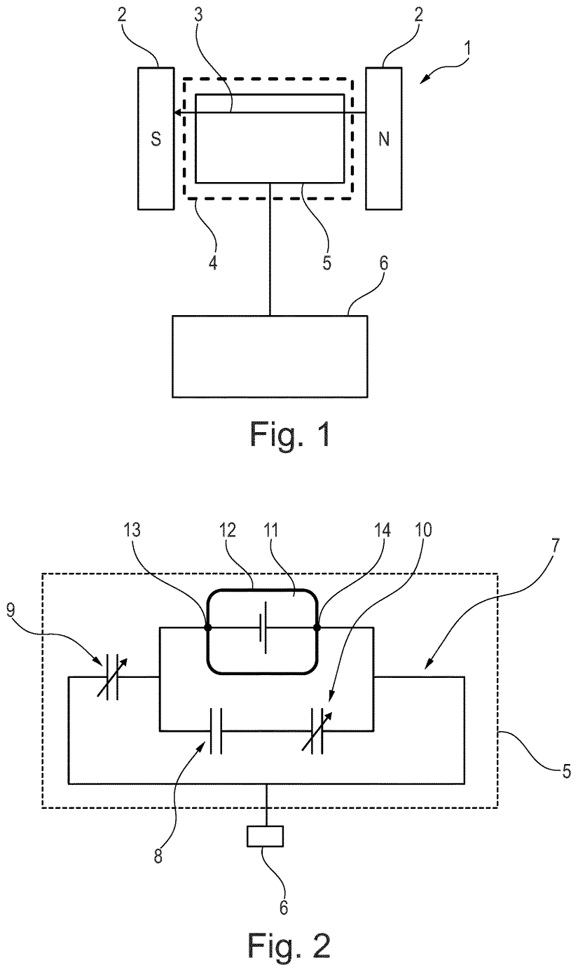

FIG. 1 shows a structure of an example of a device for examining an electrical component such as a capacitor or a battery;

FIG. 2 shows a structure of an example of a probe head for examining an electrical component such as a capacitor or a battery;

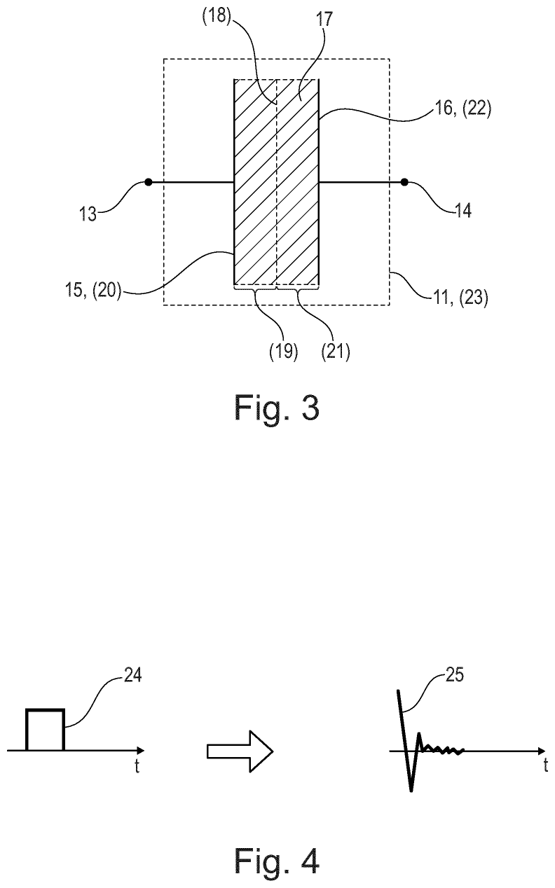

FIG. 3 very schematically shows an example of a structure of an electrical component;

FIG. 4 very schematically shows a high-frequency pulse and a spin resonance signal;

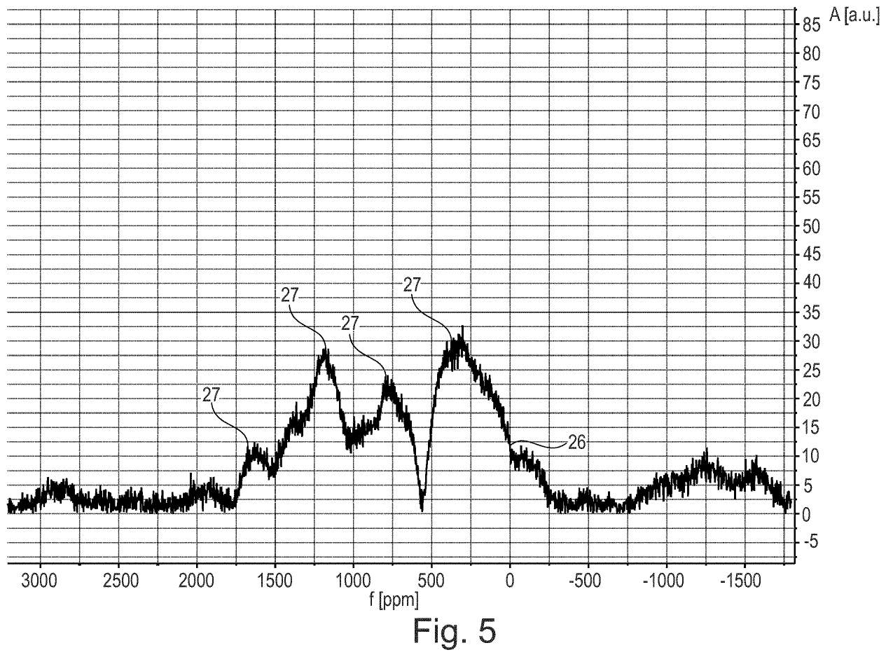

FIG. 5 shows a ¹H-NMR spectrum of an AA battery;

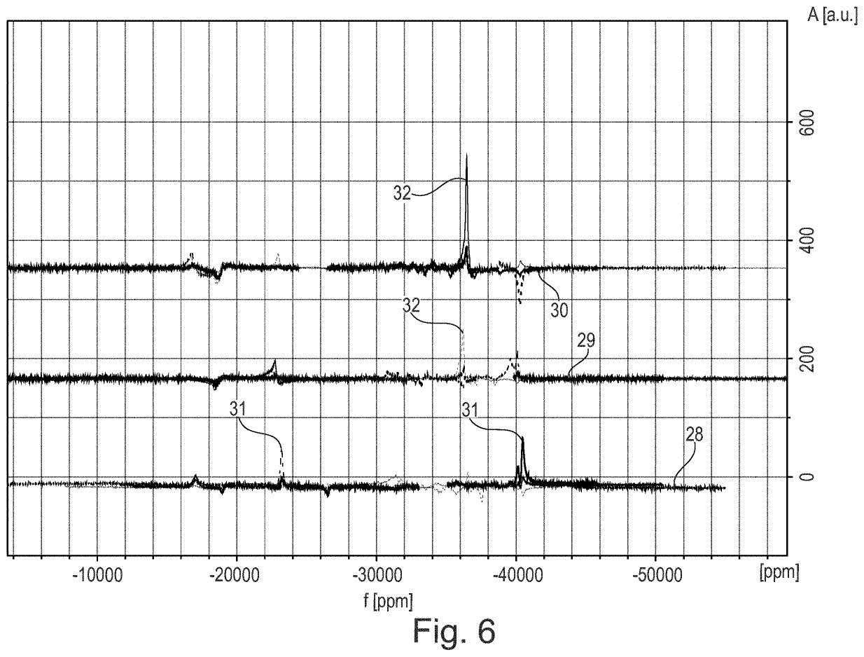

FIG. 6 shows three 1H-NMR spectra of an AA battery;

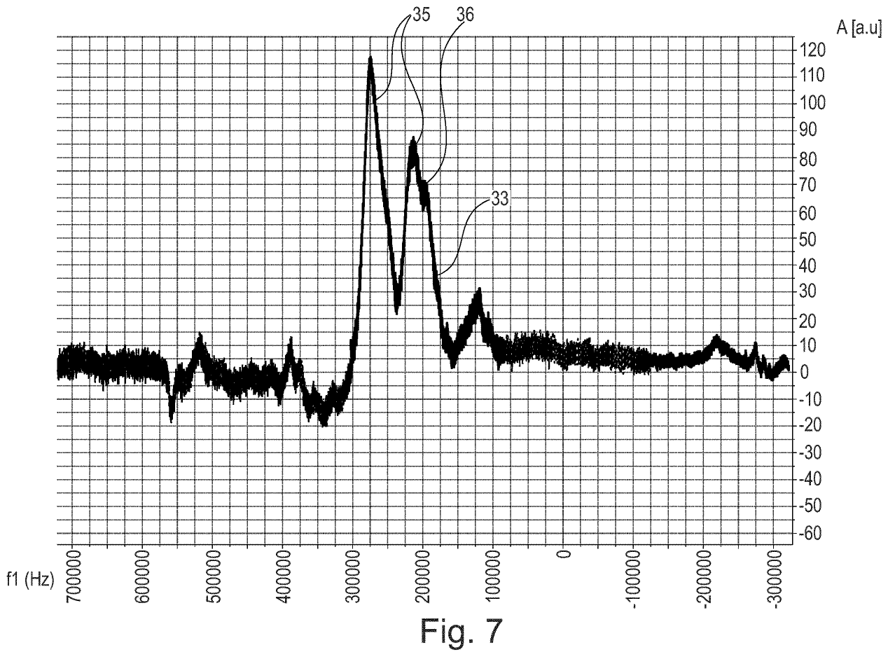

FIGS. 7 to 9 show ⁷Li spectra of an AAA battery in different states of charge;

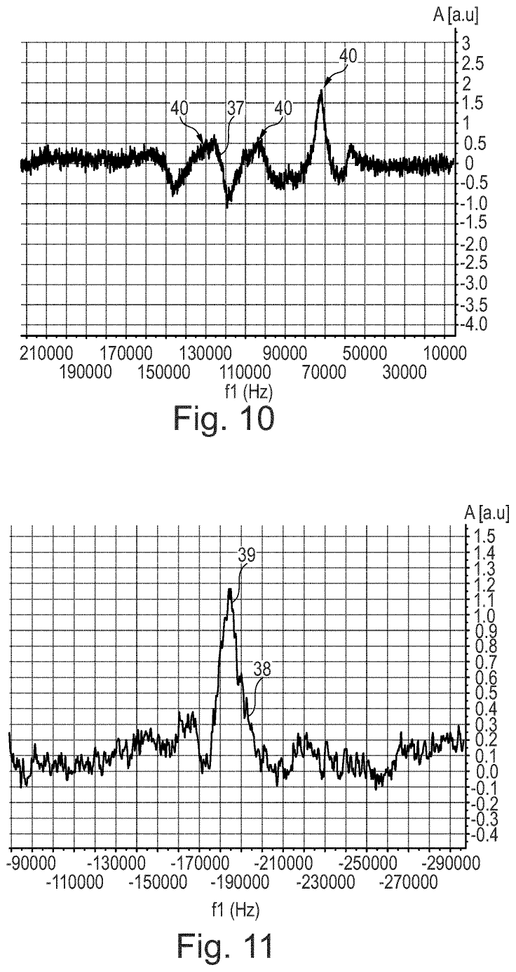

FIGS. 10 and 11 show ⁷Li spectra of a button cell, which is aligned perpendicular (FIG. 10) and parallel (FIG. 11) to the BO field;

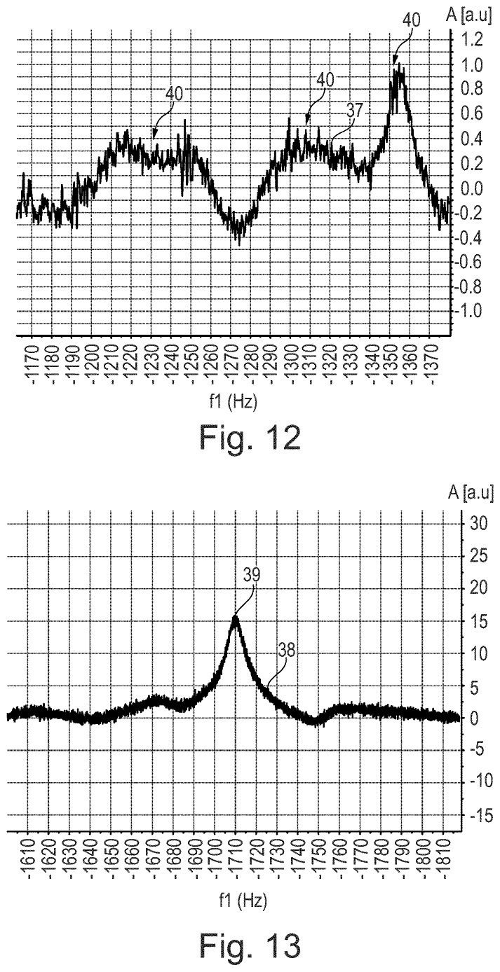

FIGS. 12 and 13 show ⁷Li spectra of a flat accumulator of a camera, which is aligned perpendicular (FIG. 12) and parallel (FIG. 13) to the BO field;

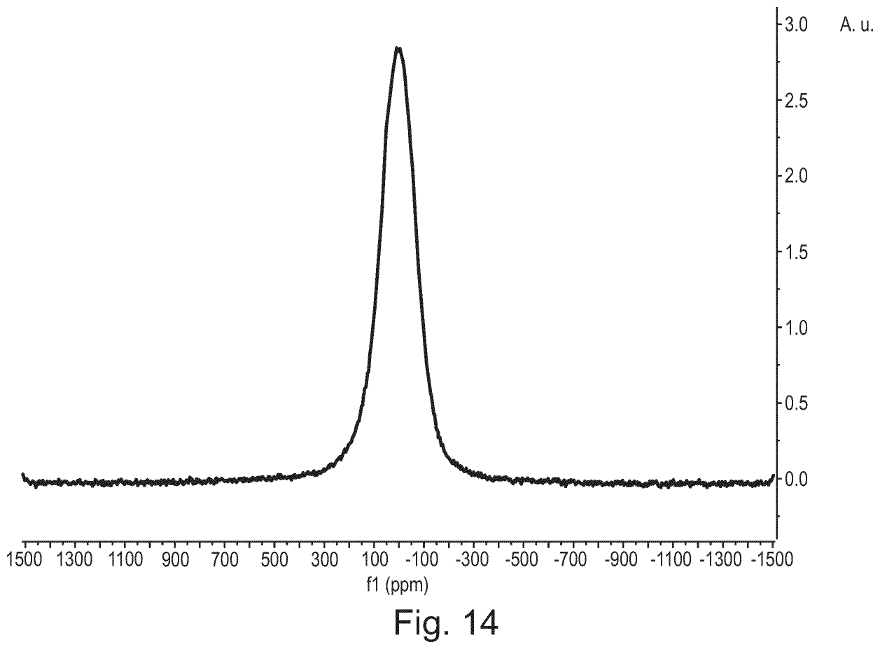

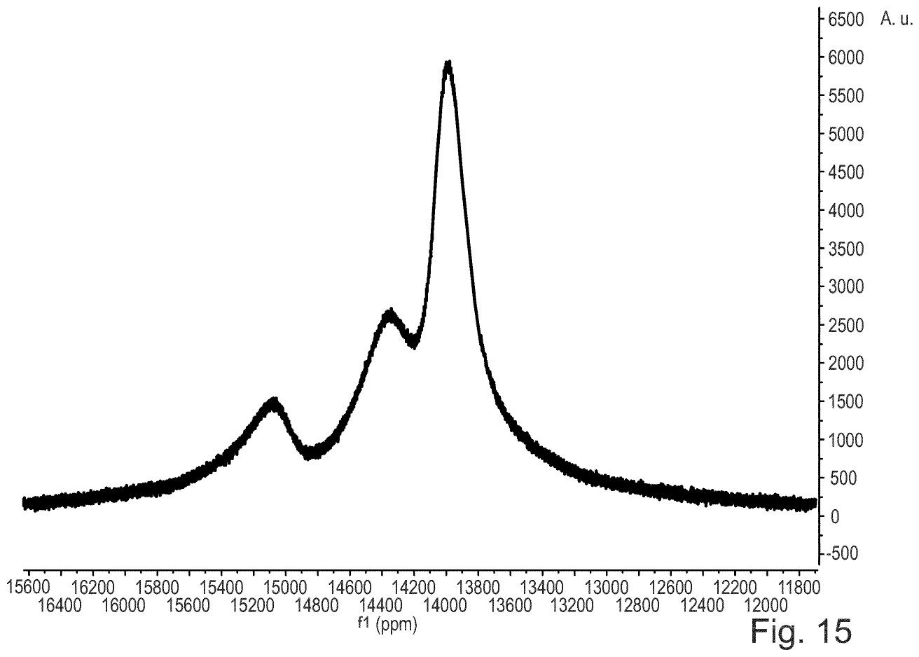

FIGS. 14 and 15 show a ⁷Li spectrum (FIGS. 14) and ⁵⁹Co spectrum (FIG. 15) of a winding of a battery of type 18650;

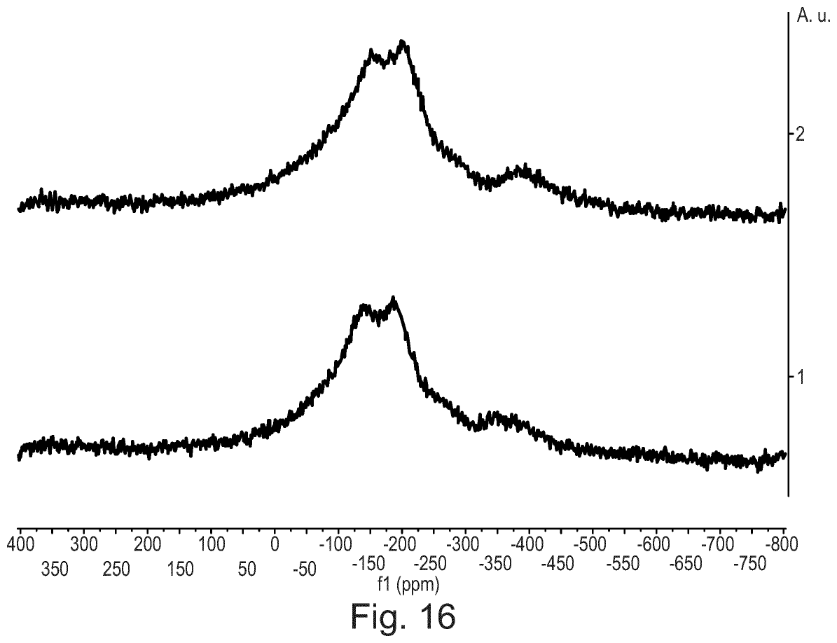

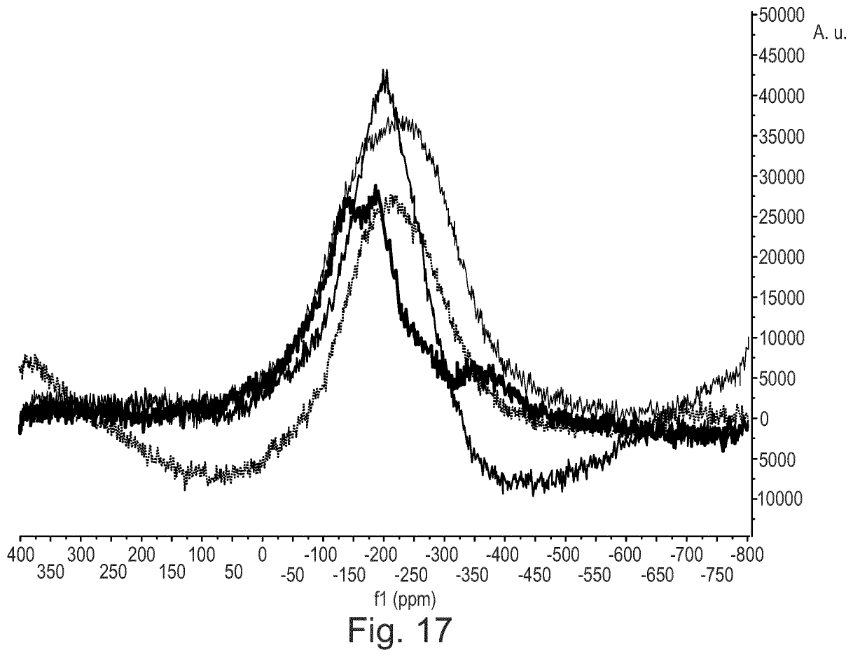

FIGS. 16 and 17 show ⁷Li spectra of various batteries of type 18650;

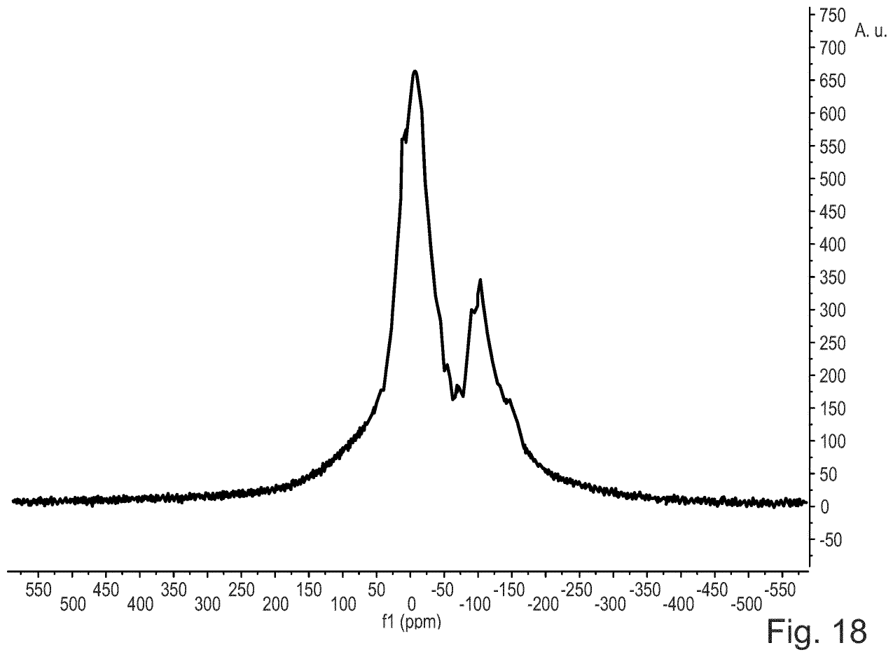

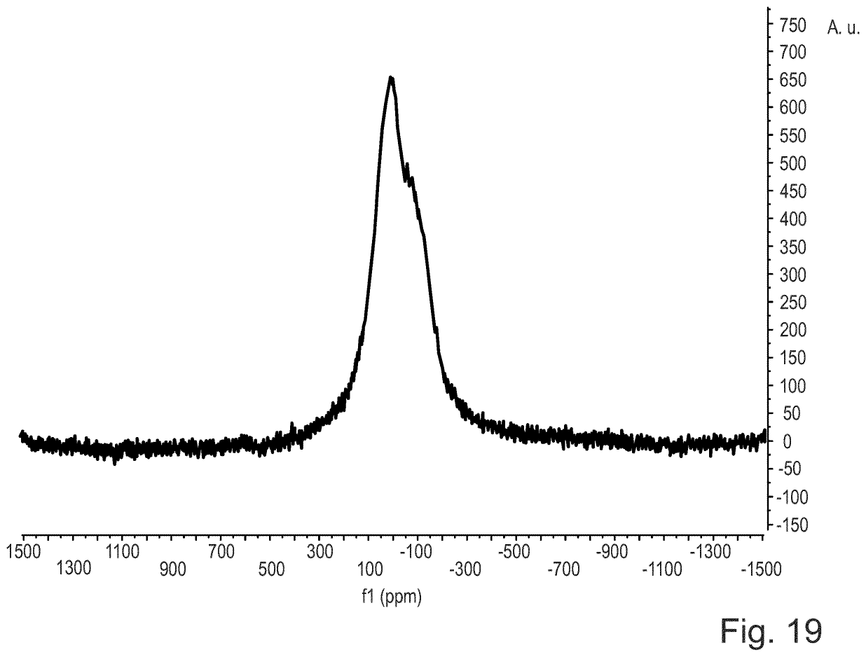

FIGS. 18 and 19 show a ¹H spectrum (FIGS. 18) and ⁷Li spectrum (FIG. 19) of a pouch bag cell;

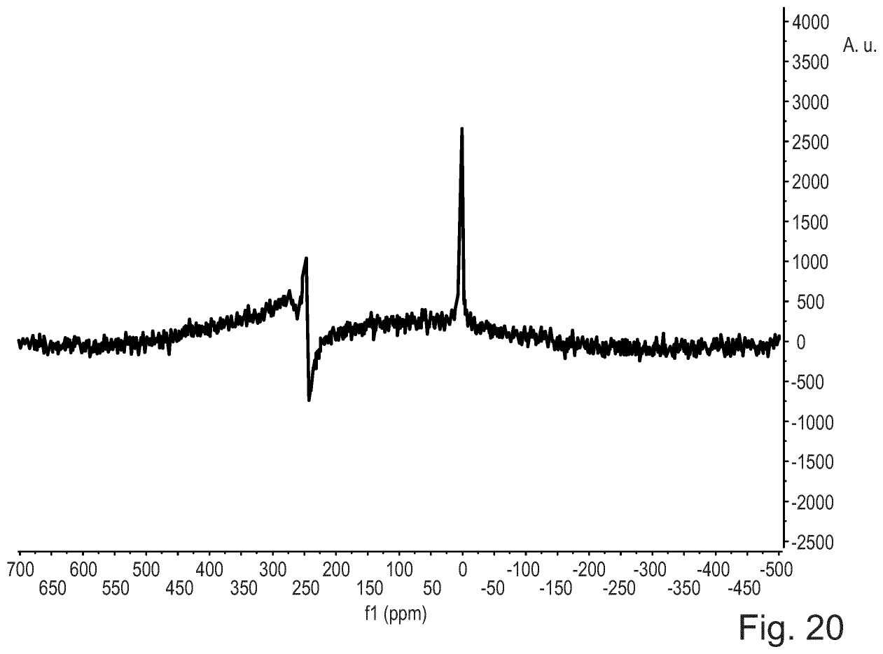

FIG. 20 shows a ⁷Li spectrum of a Swagelok cell having lithium metal and lithium-nickel-cobalt-aluminum oxide (LNCA);

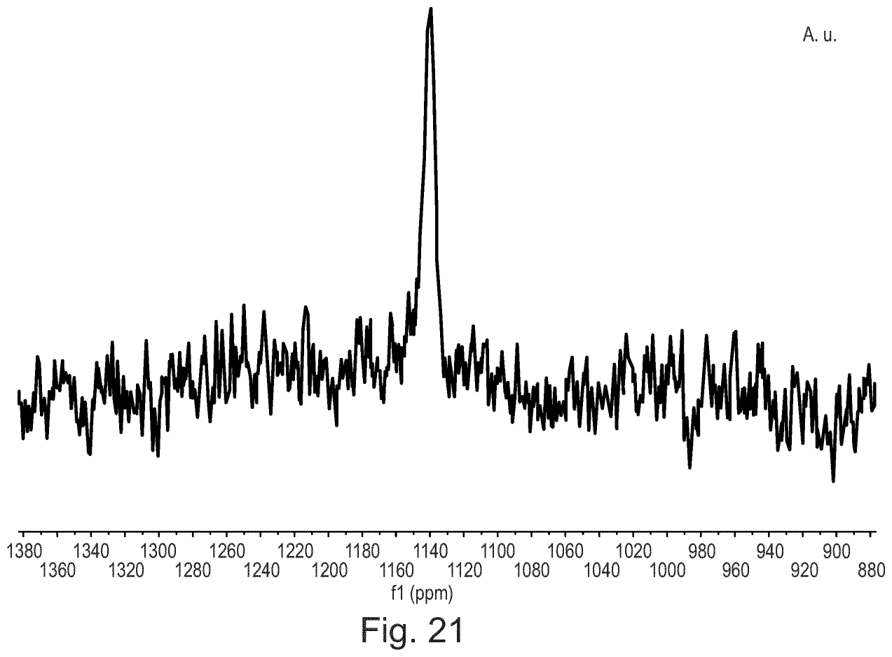

FIG. 21 shows a ²³Na spectrum of a Swagelok cell having sodium metal and hard carbon.

FIG. 1 shows a structure of a device 1 for carrying out NMR measurements on an electronic component such as a battery or a capacitor. This device 1 comprises a magnet 2, which generates a temporally and spatially homogeneous magnetic field 3. The magnet 2 is preferably a permanent magnet, an electromagnet, or a superconducting electromagnet. The magnet 2 has a sample receptacle chamber 4, in which the magnetic field 3 is sufficiently homogeneous. A temporally and spatially constant magnetic field is thus used. Alternatively, the magnetic field 3 can be made deliberately spatially inhomogeneous having at least one gradient.

A probe head 5 is introduced into the sample receptacle chamber 4 of the magnet 2. The probe head 5 is electrically connected to an NMR spectrometer 6. The probe head 5 and the NMR spectrometer 6 are electrically connected to one another. The NMR spectrometer 6 comprises, inter alia, a high-frequency transmitter and a high-frequency receiver, via which a high-frequency RF pulse can be induced in the probe head 5 and a decay of a magnetization in the probe head 5 can be detected as a spin resonance signal.

FIG. 2 schematically shows the structure of a probe head 5. It comprises a resonant circuit 7, which in this example comprises a capacitor 8, a first tunable capacitor 9, a second tunable capacitor 10 and a component 11 to be measured, which is accommodated in a component receptacle 12. The capacitor 8 is preferably designed as exchangeable in order to be able to represent further frequency ranges in the probe head 5.

The component receptacle 12 is designed such that the component 11, which has a first pole 13 and a second pole 14, is connected as shown using its poles 13, 14 to the other elements of the resonant circuit 7 by electrical contacting. The poles 13, 14 are also referred to as current collectors.

The component 11 is thus not introduced into a coil which is part of the resonant circuit 7. Rather, the battery 11 itself becomes part of the resonant circuit 7 and is incorporated in the resonant circuit 7 via the poles 13, 14. A high-frequency pulse is therefore generated using the electrical elements of the battery 11 and a decay of the magnetization arising due to the high-frequency pulse is detected using the electrical elements of the component 11 as a spin resonance signal. Surprisingly, reproducible NMR spectra are thus recordable, on the basis of which the electrical component 11 can be characterized. In particular, the detected spin resonance signal is dependent on the structure of the electrical component 11 and on the status of the electrical component 11. Everything which is formed between the two poles 13, 14 (or else current collectors) contributes to the spin resonance signal.

In the method according to the invention, a frequency of the high-frequency pulse is selected which corresponds to an NMR resonance frequency (or Larmor frequency), for example of a 1-hydrogen nucleus or of the 7-lithium nucleus at the field strength of the applied temporally and spatially constant magnetic field 3 of the magnet 2. In this way, a spin resonance signal can be obtained which is generated by the corresponding protons or 7-lithium nuclei of the further materials in the battery 11.

FIG. 3 very schematically shows an example of a structure of a component 11. In this case, this can be both a battery and a capacitor. The first pole 13 is conductively connected to a first electrode 15 and the second pole 14 is conductively connected to a second electrode 16. There is no metallic connection between the electrodes 15, 16. A substance 17, which is preferably formed as a dielectric material or electrolyte, is formed between the electrodes 15, 16. An electrode material, which is used to absorb ions, is preferably formed on the electrodes 15, 16. Furthermore, a separator is preferably formed, which prevents an electrical short circuit of the electrodes 15, 16, but permits an ionic conduction between the electrodes 15, 16. The structure shown is schematic, in particular the component can also be designed as a wound component, in which, for example, the components 15, 16 with the substance 17 are wound around one another, for example in the form of a cylindrical cell.

If the component 11 is a battery 23, the substance 17 thus regularly additionally comprises a separator 18, using which an anodic part 19 of the battery 23 having an anode 20 as the electrode 15 is separated from a cathodic part 21 of the battery 23 having a cathode 22 as the electrode 16, which is permeable to ions such as lithium ions, which travel from the anode 20 through the substance 17 formed as an electrolyte to the cathode 22 in order to generate a charge equalization. The separator 18, the battery 23, the anode 20, the anodic part 19, the cathode 22 and the cathodic part 21 are provided with reference signs in parentheses in order to emphasize the optional character of these reference signs only for the case where the component 11 is designed as a battery 23.

FIG. 4 very schematically shows, on the left side, a high-frequency pulse 24, which is introduced via the probe head 5 into the component 11 and then results in a spin resonance signal 25 as a response, which is recorded via the probe head 5. Instead of one high-frequency pulse 24, multiple high-frequency pulses 24 can also be introduced as a pulse sequence via the probe head 5 into the component 11. Not only free induction decays, but also echo signals can thus be recorded using the present method.

FIG. 5 schematically shows a proton (¹H) spectrum 26, recorded using the method described here, of a commercially available AA battery. The spectrum was measured in a temporally and spatially homogeneous magnetic field having a magnetic flux density of 1.144 T [tesla] at a resonance frequency of the high-frequency pulse of 48.409 MHz [megahertz]. The temporally and spatially homogeneous magnetic field was generated here by a conventional electromagnet. The spectrum shown is the Fourier transform of the measured spin resonance signal 25. The corresponding frequency f in ppm [parts per million] is plotted on the abscissa, while the amplitude A in arbitrary units [arbitrary units, a.u.] is plotted on the ordinate axis. Multiple peaks 27 of various widths can be seen, which are formed at different frequencies.

FIG. 6 shows three proton (¹H) spectra 28, 29, 30, recorded using the method described here, of a commercially available AA battery, which is sold under the tradename “Energizer”. The first spectrum 28, which is shown at the bottom, was recorded on the new, completely charged battery. The second spectrum 29, which is shown in the middle, was recorded on the same battery, which was, however, discharged, while the third spectrum 30, which is shown on top, was also recorded on the same discharged battery after the battery was removed from the probe head 5 and inserted back therein again. The spectra 28, 29, 30 were recorded using an identical temporally and spatially constant magnetic field of 1.207 T at a pulse length of the high-frequency pulse of 16 microseconds and 5.67 W power of the high-frequency pulse.

The first spectrum 28 of the completely charged battery shows two first main peaks 31, while the second spectrum 29 and the third spectrum 30 each show one second main peak 32. The frequency of the second main peak 32 is identical in the scope of the measurement accuracy in the second spectrum 29 and in the third spectrum 30. The frequency of the second main peak 32 clearly differs from the frequencies of the first main peak 31 in the first spectrum 28. The state of charge of a battery can therefore be determined on the basis of the method presented here.

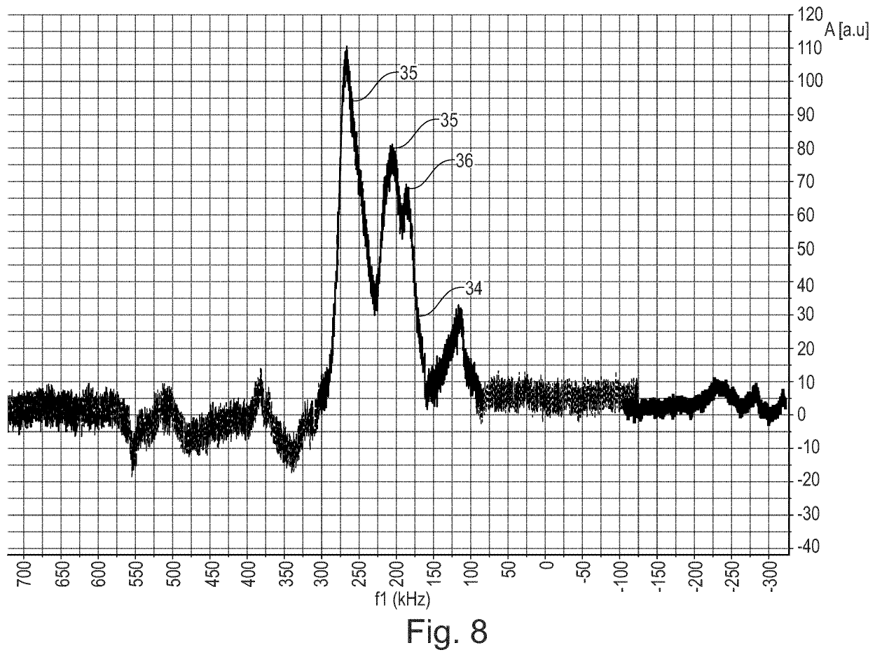

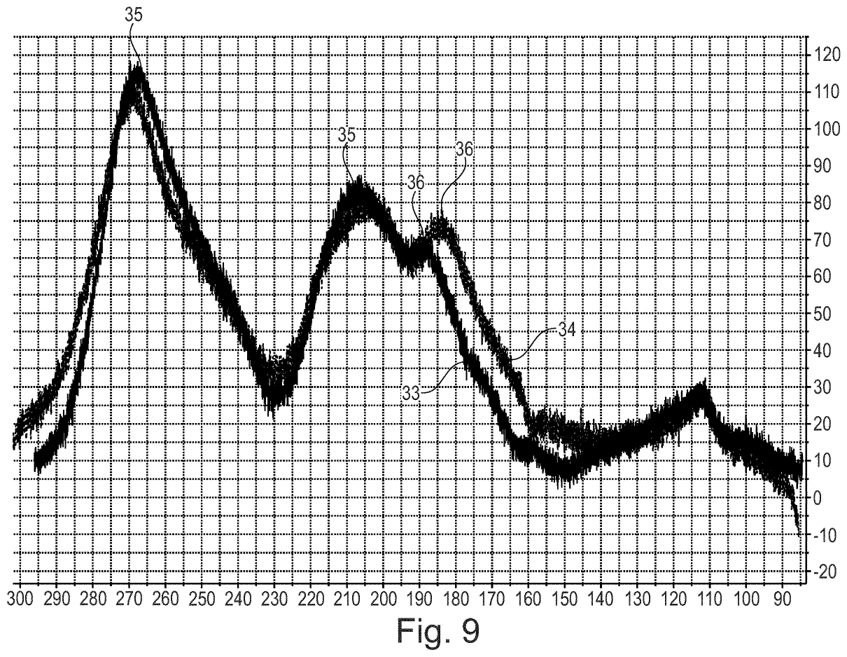

FIGS. 7 to 9 show 7-lithium (⁷Li) spectra of an AAA battery commercially sold under the tradename Varta. FIG. 7 shows a first ⁷Li spectrum of the battery in the charged state, while FIG. 8 shows a corresponding second spectrum of the battery in the discharged state. FIG. 9 shows a detail of the first spectrum 33 overlaid with the corresponding detail of the second spectrum 34. The first spectrum 33 has two main peaks 35 and one secondary peak 36. These can also be seen in the second spectrum 34, wherein the frequency of the secondary peak 36 clearly shifts in comparison to the first spectrum 33 recorded on the fully charged battery (cf. in particular FIG. 9). The state of charge of a battery can thus also be determined using 7Li-NMR measurements according to the method presented here. The measurements underlying the spectra 33, 34 were carried out with identical experimental conditions (BO field of 1.224 T, frequency of the high-frequency pulse 20.260 MHz, pulse length 2 microseconds at 20 watts power).

While the AA and AAA batteries observed in the previous figures represent elongated cylinders, i.e. an end surface of the cylinder is smaller than the lateral surface of the cylinder, FIGS. 10 to 13 show ⁷Li-NMR spectra, which were recorded on flat batteries or more generally on batteries having a flat structure having two largest surfaces opposite to one another, each of which is larger than the other surfaces. FIGS. 10 and 11 show ⁷Li spectra, which were recorded on a charged button cell sold under the tradename Conrad LIR2450, while FIGS. 12 and 13 show ⁷Li spectra which were carried out on a charged cuboid battery for cameras from Canon. The spectra recorded in FIGS. 10 and 11 were recorded with a BO field of approximately 1.031 T (corresponds to a Larmor frequency of ⁷Li of approximately 17.06 MHz), while the spectra in FIGS. 12 and 13 were recorded with a BO field of 1.070 T (corresponds to a Larmor frequency of approximately 17.706 MHz).

FIGS. 10 and 12 show first spectra 37 which were recorded in a structure in which the largest surface of the battery was aligned perpendicular to the BO field, while FIGS. 11 and 13 show second spectra 38 which were recorded in a structure in which the largest surface was aligned parallel to the BO field. The second spectra 38 in FIGS. 11 and 13 are each distinguished by a single main peak 39, while the first spectra 37 show multiple peaks 40. The alignment of flat components such that the largest surface is aligned parallel to the BO field is preferred since in this way an unambiguous spectrum can be obtained. This spectrum too is dependent on the state of charge of the battery.

The method described here permits NMR measurements to be carried out on electrical components such as batteries or capacitors. For this purpose, the component directly becomes part of a resonant circuit 7 of an NMR probe head 5, in that the poles 13, 14 are electrically connected to the other elements of the resonant circuit 7 and then the probe head 5 is introduced into a temporally and spatially constant magnetic field 3. Pulse NMR measurements are carried out in which a spin resonance signal 25 is generated by at least one high-frequency pulse 24 and recorded. The spectrum 26, 28, 29, 30, 33, 34, 37, 38 formed from this spin resonance signal 25 is dependent on the status of the component 11, in particular on the state of charge of a battery or on the general status of the battery or of the capacitor.

FIG. 14 shows a ⁷Li spectrum and FIG. 15 shows a ⁵⁹Co spectrum of a winding of a battery of type 18650 LCO. The winding used was prepared for the assembly of a battery of type 18650. The winding was used as a resonator. The winding was coated on one electrode using carbon and on the other electrode using lithium cobalt oxide as the active material.

FIGS. 16 and 17 show ⁷Li spectra of various batteries of type 18650. FIG. 16 shows the spectra of two commercially available batteries having the designation Samsung 35E Li. This example shows that the spectra of various batteries of the same series from a producer are similar to one another. Chemical information can also be obtained even with commercially available batteries of type 18650.

The spectra shown in FIG. 16 were recorded by means of NMR at 400 MHz. The spectra of four commercially available batteries from different producers are shown in FIG. 17: Samsung 35E Li, Panasonic NCR 18650D, LG INR 18650-M29 and Samsung ICR 30B. This example shows that the spectra of batteries from different producers are different.

FIG. 18 shows a ¹H spectrum of a pouch bag cell of the type “LCO vs. Carbon”. FIG. 19 shows a ⁷Li spectrum of this pouch bag cell.

FIG. 20 shows a ⁷Li spectrum of a Swagelok cell having lithium metal and lithium-nickel-cobalt-aluminum oxide (LNCA). This is also referred to as “LNCA vs. Li in operando”.

FIG. 21 shows a ²³Na spectrum of a Swagelok cell having lithium metal and hard carbon. This is also referred to as “Carbon vs. Na”.

### REFERENCE SIGNS

1 device for characterizing a battery
2 magnet
3 temporally and spatially constant magnetic field
4 sample receptacle chamber
5 probe head
6 NMR spectrometer
7 resonant circuit
8 capacitor
9 first tunable capacitor
10 second tunable capacitor
11 component
12 component receptacle
13 first pole
14 second pole
15 first electrode
16 second electrode
17 substance
18 separator
19 anodic part
20 anode
21 cathodic part
22 cathode
23 battery
24 high-frequency pulse
25 spin resonance signal
26 spectrum
27 peak
28 first spectrum
29 second spectrum
30 third spectrum
31 first main peak
32 second main peak
33 first spectrum
34 second spectrum
35 main peak
36 secondary peak
37 first spectrum
38 second spectrum
39 main peak
40 peak

1. A method for examining an electrical component having a first pole and a second pole,
wherein the component is electrically connectable via the poles
wherein the component has two electrodes, wherein one electrode is electrically connected in each case to precisely one pole and the component does not have a metallic connection between the electrodes wherein a substance is formed in the component between the electrodes
wherein the component is subjected to a temporally constant magnetic field and a high-frequency field switched in pulses and the data are measured in the form of at least one spin resonance signal,
characterized in that
the component is electrically incorporated via its poles in a resonant circuit, via which the high-frequency field is excited inside the component and the spin resonance signal is recorded.

2. The method as claimed in claim 1, in which the resonant circuit comprises at least two tunable capacitors, via which the frequency and impedance of the resonant circuit is adaptable.

3. The method as claimed in claim 1, in which the substance comprises an electrolyte.

4. The method as claimed in claim 1, in which the substance comprises a dielectric material.

5. The method as claimed in claim 1, in which the component comprises a capacitor.

6. The method as claimed in claim 1, in which the component comprises a battery or a winding for a battery.

7. The method as claimed in claim 1, in which the resonance frequency of one of the following atomic nuclei is determined on the basis of the magnetic flux density of the spatially and temporally constant magnetic field: 1-hydrogen (¹H); 6-lithium (⁶Li); 7-lithium (⁷Li); 13-carbon (¹³C); 14-nitrogen (14N); 19-fluorine (¹⁹F); 23-sodium (²³Na); 27-aluminum (²⁷Al); 29-silicon (²⁹Si); 31-phosphorus (³¹P); 39-potassium (³⁹K); 59-cobalt (⁵⁹Co) or 207-lead (²⁰⁷Pb), and this resonance frequency is used as the frequency of the high-frequency field.

8. The method as claimed in claim 1, in which the component has a cylindrical structure having a cylinder axis, and the cylinder axis is aligned in the direction of the magnetic flux of the temporally and spatially homogeneous magnetic field.

9. The method as claimed in claim 1, in which the component has a flat structure having two opposing largest surfaces and the component is aligned such that the largest surface is aligned in the direction of the magnetic flux of the temporally and spatially homogeneous magnetic field.

10. The method as claimed in claim 1, in which the temporally constant magnetic field is spatially constant.

11. The method as claimed in claim 1, in which the temporally constant magnetic field has a gradient in at least one spatial direction.

12. The method as claimed in claim 2, in which the substance comprises an electrolyte.

13. The method as claimed in claim 2, in which the substance comprises a dielectric material.

14. The method as claimed in claim 2, in which the component comprises a capacitor.

15. The method as claimed in claim 2, in which the component comprises a battery or a winding for a battery.

16. The method as claimed in claim 2, in which the resonance frequency of one of the following atomic nuclei is determined on the basis of the magnetic flux density of the spatially and temporally constant magnetic field: 1-hydrogen (¹H); 6-lithium (⁶Li); 7-lithium (⁷Li); 13-carbon (¹³C); 14-nitrogen (14N); 19-fluorine (¹⁹F); 23-sodium (²³Na); 27-aluminum (²⁷Al); 29-silicon (²⁹Si); 31-phosphorus (³¹P); 39-potassium (³⁹K); 59-cobalt (⁵⁹Co) or 207-lead (²⁰⁷Pb), and this resonance frequency is used as the frequency of the high-frequency field.

17. The method as claimed in claim 2, in which the component has a cylindrical structure having a cylinder axis, and the cylinder axis is aligned in the direction of the magnetic flux of the temporally and spatially homogeneous magnetic field.

18. The method as claimed in claim 2, in which the component has a flat structure having two opposing largest surfaces and the component is aligned such that the largest surface is aligned in the direction of the magnetic flux of the temporally and spatially homogeneous magnetic field.

19. The method as claimed in claim 2, in which the temporally constant magnetic field is spatially constant.

20. The method as claimed in claim 2, in which the temporally constant magnetic field has a gradient in at least one spatial direction.
